(19) United States
(12) Patent Application Publication
(10) Pub. No.: US 2025/0208979 A1
(43) Pub. Date: Jun. 26, 2025

(54) HOST-TO-HOST TRANSFER OF DEBUG DATA

(71) Applicant: Advanced Micro Devices, Inc., Santa Clara, CA (US)

(72) Inventors: Kong Ling, Shanghai (CN); Paul A. Simoncic, Santa Clara, CA (US); Jagadish Hadimani, Bangalore (IN)

(73) Assignee: Advanced Micro Devices, Inc., Santa Clara, CA (US)

(21) Appl. No.: 18/390,965

(22) Filed: Dec. 20, 2023

(51) Int. Cl. G06F 11/36

(52) U.S. Cl. CPC G06F 11/362

(57) ABSTRACT

Devices, methods, and systems for communicating debugging information. Debugging information is stored from debugging hardware of an integrated circuit into a memory of the integrated circuit. The debugging information is retrieved from the memory and encapsulating the debugging information in a packet. The packet is transmitted over an interface to a device that is external to the integrated circuit. In some implementations, the debugging information is stored in MMIO space of the memory that is not mapped to registers of the integrated circuit. In some implementations, the debugging information is stored in a MMIO space of the memory, wherein a base address of the MMIO is indicated in a base address register (BAR) of the integrated circuit. In some implementations, the debugging information is encapsulated in a USB4 packet and transmitted over a USB4 interface to the device that is external to the integrated circuit.

### BACKGROUND

Modern computing devices include numerous electronic circuits on a single substrate, on a single die, or within a single package, for example. Such devices may include integrated circuits (ICs), such as System-on-Chip (SoC) devices, that include circuitry that would have been implemented using several separate circuit boards in the past. Accordingly, signals that would have been easily testable in the past are no longer easily accessible for testing.

The process of discovering errors in such devices can be referred to as silicon debugging, and is typically performed before high-volume manufacturing of the device. Silicon debugging typically includes identifying and resolving issues related to component functionality or performance.

Silicon debugging of a device such as an SoC, or other IC, may be performed using circuitry embedded within the device. Embedded silicon debugging circuitry may include scan chains, test access ports (TAPs), and built-in-self-test (BIST) circuits, for example. Embedded silicon debugging circuitry may be used to generate silicon debug data pertaining to the internal state of the device.

### BRIEF DESCRIPTION OF THE DRAWINGS

A more detailed understanding can be had from the following description, given by way of example in conjunction with the accompanying drawings wherein:

FIG. 1 is a block diagram of an example device in which one or more features of the disclosure can be implemented;

FIG. 2 is a block diagram illustrating an example debugging target;

FIG. 3 is a block diagram illustrating an example system configured for silicon debugging;

FIG. 4 is a block diagram illustrating another example system configured for silicon debugging;

FIG. 5 is a block diagram illustrating another example system configured for silicon debugging;

FIG. 6 is a flow chart illustrating an example procedure for transmitting debugging information from a debugging target to a debugging host;

FIG. 7 is a flow chart illustrating an example procedure implemented in a system including a debugging target and a debugging host;

FIG. 8 is a flow chart illustrating an example procedure implemented in a debugging host for receiving a packet from a debugging target and de-encapsulating the packet to recover and process debugging information;

FIG. 9 is a block diagram illustrating an example system for silicon debugging; and

FIG. 10 is a block diagram illustrating another example system for silicon debugging.

### DETAILED DESCRIPTION

It may be desired to retrieve debugging information from an integrated circuit at a relatively high speed and/or without using dedicated package pins or external hardware support. Accordingly, in some implementations, a processor retrieves the debugging information from memory, encapsulates the debugging information in a packet, and transmits the packet to a device that is external to the integrated circuit over a communication interface (e.g., a Universal Serial Bus 4 (USB4) Host-to-Host interface).

Some implementations provide a device configured for communicating debugging information. The device includes circuitry configured to store debugging information from debugging hardware of the device into a memory of the device. The device also includes circuitry configured to retrieve the debugging information from the memory and encapsulate the debugging information in a packet. The device also includes circuitry configured to transmit the packet over an interface to another device that is external to the device.

In some implementations, the debugging information is stored in memory mapped input output (MMIO) space of the memory. In some implementations, the debugging information is stored in MMIO space of the memory that is not mapped to registers of the device. In some implementations, the debugging information is stored in a MMIO space of the memory, wherein a base address of the MMIO is indicated in a base address register (BAR) of the device. Some implementations include circuitry configured to encapsulate the debugging information in a Universal Serial Bus 4 (USB4) packet and to transmit the packet over a USB4 interface to the device that is external to the device. Some implementations include circuitry configured to retrieve the debugging information is retrieved from the memory, encapsulate the debugging information in a packet, and pass the packet to a USB4 driver for transmission over the interface to the device that is external to the device. In some implementations, the device transmits the packet to the device that is external to the device via a Universal Serial Bus C (USB-C) interface, USB4 fabric, and/or USB4 Host-to-Host Tunneling. In some implementations, the packet comprises a USB4 interdomain packet or an internet protocol (IP) packet. In some implementations, the memory of the device comprises dynamic random-access memory (DRAM). In some implementations, encapsulating the debugging information in a packet comprises encapsulating the debugging information in a USB4 Interdomain Packet.

Some implementations provide a method for communicating debugging information. Debugging information is stored from debugging hardware of an integrated circuit into a memory of the integrated circuit. The debugging information is retrieved from the memory and encapsulating the debugging information in a packet. The packet is transmitted over an interface to a device that is external to the integrated circuit.

In some implementations, the debugging information is stored in MMIO space of the memory. In some implementations, the debugging information is stored in MMIO space of the memory that is not mapped to registers of the integrated circuit. In some implementations, the debugging information is stored in a MMIO space of the memory, wherein a base address of the MMIO is indicated in a base address register (BAR) of the integrated circuit. In some implementations, the debugging information is encapsulated in a USB4 packet and transmitted over a USB4 interface to the device that is external to the integrated circuit. In some implementations, the debugging information is retrieved from the memory, encapsulated in a packet, and passed to a USB4 driver for transmission over the interface to the device that is external to the integrated circuit. In some implementations, the integrated circuit transmits the encapsulated debugging information to the device that is external to the integrated circuit via a USB-C interface, USB4 fabric, and/or USB4 Host-to-Host Tunneling. In some implementations, the packet comprises a USB4 interdomain packet or an IP packet. In some implementations, the memory of the integrated circuit comprises DRAM. In some implementations, encapsulating the debugging information in a packet comprises encapsulating the debugging information in a USB4 Interdomain Packet.

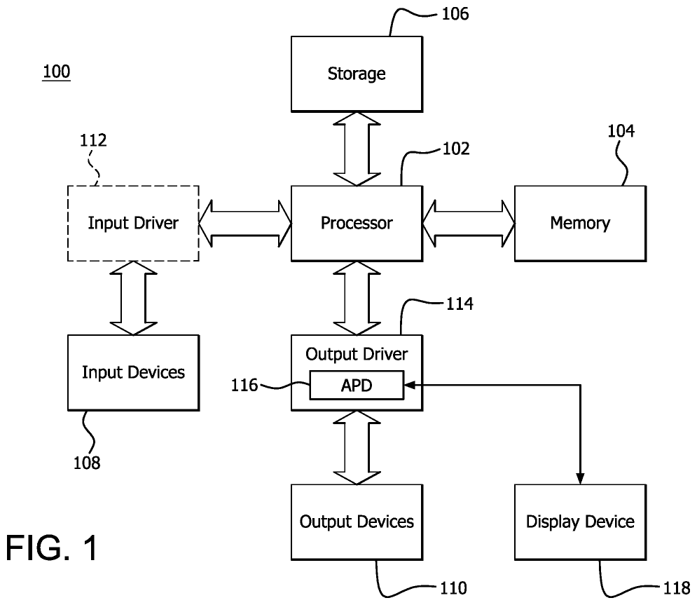

FIG. 1 is a block diagram of an example device 100 in which one or more features of the disclosure can be implemented. The device 100 can include, for example, a computer, a gaming device, a handheld device, a set-top box, a television, a mobile phone, server, a tablet computer or other types of computing devices. The device 100 includes a processor 102, a memory 104, a storage 106, one or more input devices 108, and one or more output devices 110. The device 100 can also optionally include an input driver 112 and an output driver 114. It is understood that the device 100 can include additional components not shown in FIG. 1.

In various alternatives, the processor 102 includes a central processing unit (CPU), a graphics processing unit (GPU), a CPU and GPU located on the same die, or one or more processor cores, wherein each processor core can be a CPU or a GPU. In some implementations, processor 102 is implemented as an SoC. In various alternatives, the memory 104 is located on the same die as the processor 102 (e.g., as part of an SoC), or is located separately from the processor 102. The memory 104 includes a volatile or non-volatile memory, for example, random access memory (RAM), dynamic RAM, or a cache.

The storage 106 includes a fixed or removable storage, for example, a hard disk drive, a solid-state drive, an optical disk, or a flash drive. The input devices 108 include, without limitation, a keyboard, a keypad, a touch screen, a touch pad, a detector, a microphone, an accelerometer, a gyroscope, a biometric scanner, or a network connection (e.g., a wireless local area network card for transmission and/or reception of wireless IEEE 802 signals). The output devices 110 include, without limitation, a display device 118, a display connector/interface (e.g., an HDMI or DisplayPort connector or interface for connecting to an HDMI or Display Port compliant device), a speaker, a printer, a haptic feedback device, one or more lights, an antenna, or a network connection (e.g., a wireless local area network card for transmission and/or reception of wireless IEEE 802 signals).

The input driver 112 communicates with the processor 102 and the input devices 108, and permits the processor 102 to receive input from the input devices 108. The output driver 114 communicates with the processor 102 and the output devices 110, and permits the processor 102 to send output to the output devices 110. It is noted that the input driver 112 and the output driver 114 are optional components, and that the device 100 will operate in the same manner if the input driver 112 and the output driver 114 are not present. The output driver 116 includes an accelerated processing device (“APD”) 116 which is coupled to a display device 118. The APD accepts compute commands and graphics rendering commands from processor 102, processes those compute and graphics rendering commands, and provides pixel output to display device 118 for display. As described in further detail below, the APD 116 includes one or more parallel processing units to perform computations in accordance with a single-instruction-multiple-data (“SIMD”) paradigm. Thus, although various functionality is described herein as being performed by or in conjunction with the APD 116, in various alternatives, the functionality described as being performed by the APD 116 is additionally or alternatively performed by other computing devices having similar capabilities that are not driven by a host processor (e.g., processor 102) and provides graphical output to a display device 118. For example, it is contemplated that any processing system that performs processing tasks in accordance with a SIMD paradigm may perform the functionality described herein. Alternatively, it is contemplated that computing systems that do not perform processing tasks in accordance with a SIMD paradigm can also perform the functionality described herein.

As discussed above, SoC devices combine multiple electronic components or functions of a computer, or other electronic system, onto an IC. SoCs typically include a microprocessor or microcontroller, memory, input/output interfaces, and peripheral devices.

One problem in silicon debugging of ICs (such as SoC devices and other devices) lies in efficiently transferring large amounts of captured debug data off of the integrated circuit. Some approaches to transferring captured debug data out of the integrated circuit include transmitting the captured debug data through package pins of the SoC (or other IC, or closed chassis system). It is noted however that in some cases suitable package pins are unavailable, or it would be preferable to dedicate package pins to other purposes.

Other approaches to transfer of captured debug data out of the SoC, or other IC, or closed chassis system, include transmitting the captured debug data through a Joint Test Action Group (JTAG) interface, however JTAG interfaces are relatively slow and in some implementations are not available in a closed chassis design. Accordingly, it may be advantageous to provide methods, devices, systems, and so forth for transferring debug data out of an integrated circuit which do not require extra hardware and/or are faster than existing techniques.

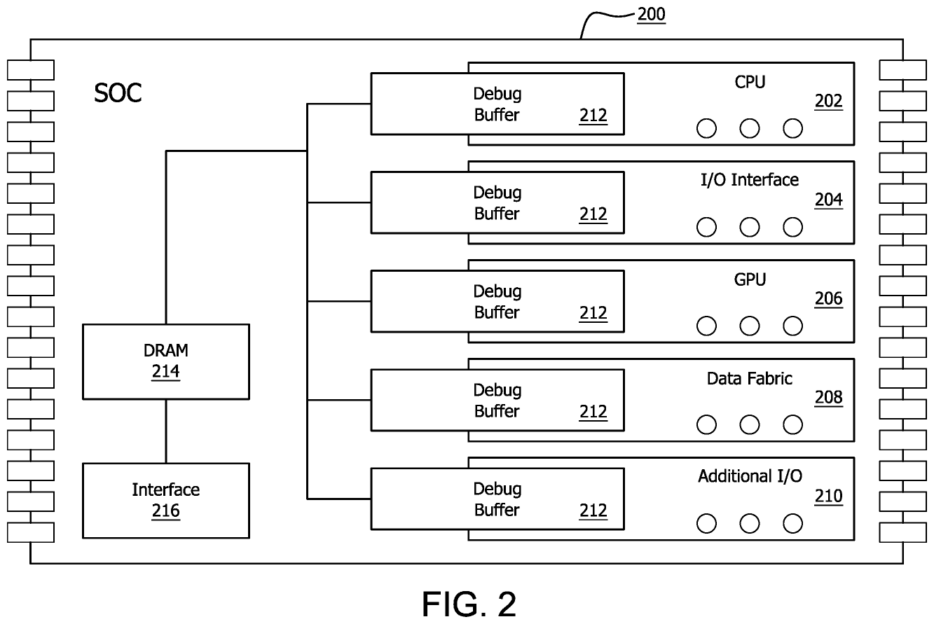

FIG. 2 is a block diagram illustrating an example debugging target 200. In this example, debugging target is an SoC. In other examples, any suitable IC or closed chassis system is usable as a debugging target. For example, a debugging target such as debugging target 200 may include some or all (or any one) of the components of device 100 as shown and described with respect to FIG. 1.

In this example, debugging target 200 includes several components, including a CPU 202, input-output interfaces 204, GPU 206, data fabric 208, and additional input-output interfaces 210. It is noted that these components are exemplary only, and in some implementations an SoC includes additional components, fewer components, a subset of these components, and/or different components.

Each of the components includes or is in communication with a debugging circuit 212. Debugging circuitry 212 sends signals to the respective components, e.g., under test, in order to collect debugging information in response to the signals. In some implementations, debugging circuitry 212 includes buffer circuitry which stores the debugging information before the debugging information is transferred into memory or elsewhere.

In this example, memory 214 includes dynamic random-access memory (DRAM), however it is noted that any other suitable type of memory is usable in other implementations. Debugging interface 216 is a JTAG test access port (TAP) in this example, however it is noted that any other suitable type of debugging interface is usable in other implementations.

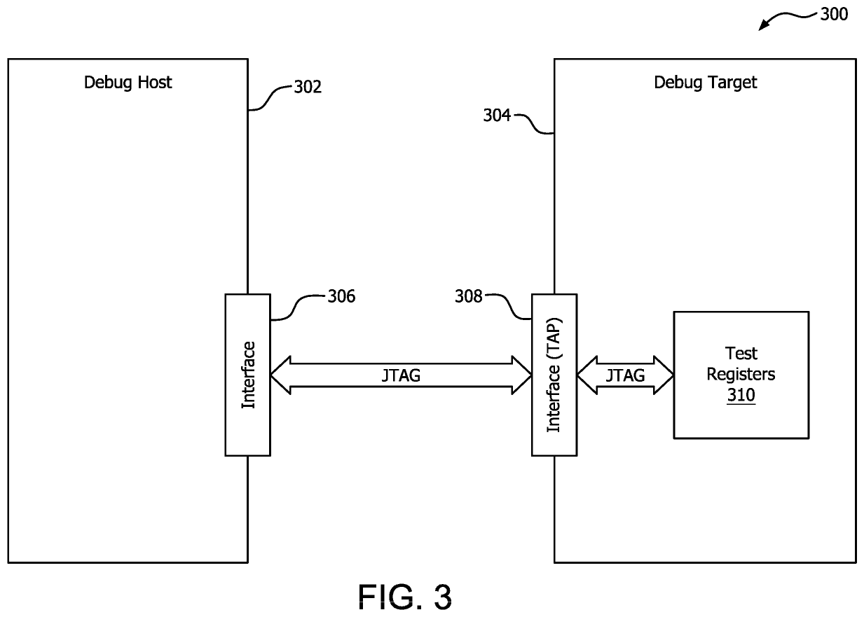

FIG. 3 is a block diagram illustrating an example system 300 configured for silicon debugging. System 300 includes a debugging host 302, and a debugging target 304.

Debugging host 302 includes any suitable computing system or other electronic hardware configured to receive debugging data from a debugging target for debugging (e.g., silicon debugging) purposes, such as analysis of signals. In some implementations, debugging data includes debugging signal samples from devices on a debugging target, such as debug target 304. Debugging host 302 includes a communications interface 306.

Debugging target 304 includes any suitable debugging target, such as debugging target 200 as shown and described with respect to FIG. 2, or any suitable SoC or other IC or closed chassis system. In this example, debugging target 304 includes a communications interface 308 and test registers 310. Debugging host 302 sends debugging commands and/or other information (e.g., to stimulate circuitry under test to generate debugging information) to debugging target 304 via communications interfaces 306 and 308. Debugging target 304 generates debugging information responsive to the debugging commands (storing the debugging information in test registers 310 in this example) and transmits the debugging information from test registers 310 to the debugging host 302 via communications interface 308 and communications interface 306.

In this example, communications interface 308 and communications interface 306 are JTAG interfaces, and the debugging information is transmitted in JTAG format. In some implementations, direct access to a JTAG TAP of debugging target 304 is needed in order to transmit the debugging information in this way. In some implementations, transmitting debugging information in this way is relatively slow as compared with other computer communications interfaces.

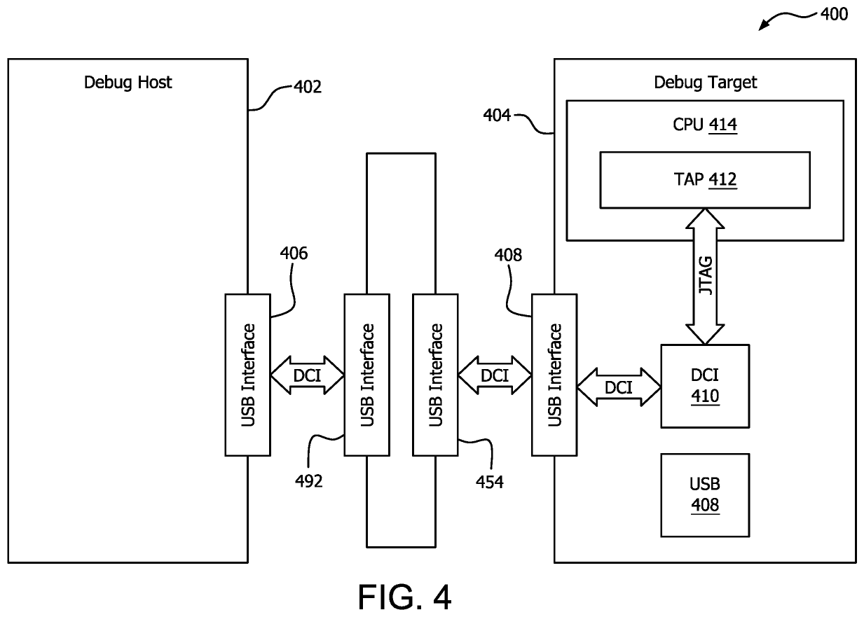

FIG. 4 is a block diagram illustrating an example system 400 configured for silicon debugging. System 400 includes a debugging host 402, and a debugging target 404.

Debugging host 402 includes any suitable computing system or other electronic hardware configured to receive debugging data from a debugging target for debugging (e.g., silicon debugging) purposes, such as analysis of signals.

Debugging host 402 includes a communications interface 406, which can include any suitable communications interface, such as Ethernet. Debugging target 404 includes any suitable debugging target, such as debugging target 200 as shown and described with respect to FIG. 2, or any suitable SoC or other IC or closed chassis system. In this example, debugging target 404 includes a communications interface 408.

In this example, communications interface 408 comprises a Universal Serial Bus (USB) port, and debugging commands and information are transmitted in Direct Connect Interface (DCI) format over the USB port of communications interface 408 (e.g., USB 2.0, or USB 3.0). In other words, the debugging commands and information are transmitted using the USB physical layer (PHY) using DCI format instead of USB format. Accordingly, DCI interface 410 communicates debugging commands to JTAG TAP 412 of CPU 414 on debug target 404, and DCI interface 410 communicates debugging information from JTAG TAP 412 of CPU 414 (or any other device being debugged) on debug target 404. It is noted that DCI format is an example, and that in some implementations any suitable format is used over the USB PHY.

In some implementations, communications interface 408 is a USB host interface. It is noted that some versions of USB, such as USB 2.0 and USB 3.0, do not provide facility for communicating directly between USB host interfaces. Accordingly, debugging target 404 receives debugging commands from debugging host 402 and transmits debugging information to debugging host 402 through communications interface 408 and communications interface 406, via an intermediary device 450.

Intermediary device 450 includes communications interface 452 and communications interface 454. Communications interface 452 is an Ethernet interface, in this example, and communications interface 454 is a USB device (i.e., client) interface. Intermediary device 450 includes circuitry configured to communicate information (e.g., debugging information) between communications interface 452 and communications interface 454 such that debugging target 404 is able to receive debugging commands from debugging host 402 and to transmit debugging information to the debugging host 402 via communications interface 408 and communications interface 406, via intermediary device 450.

In some implementations, it is disadvantageous to use an intermediary device to transmit debugging information in this way, e.g., due to increased cost, complexity, and data latency due to hardware and/or software of the intermediary device 450.

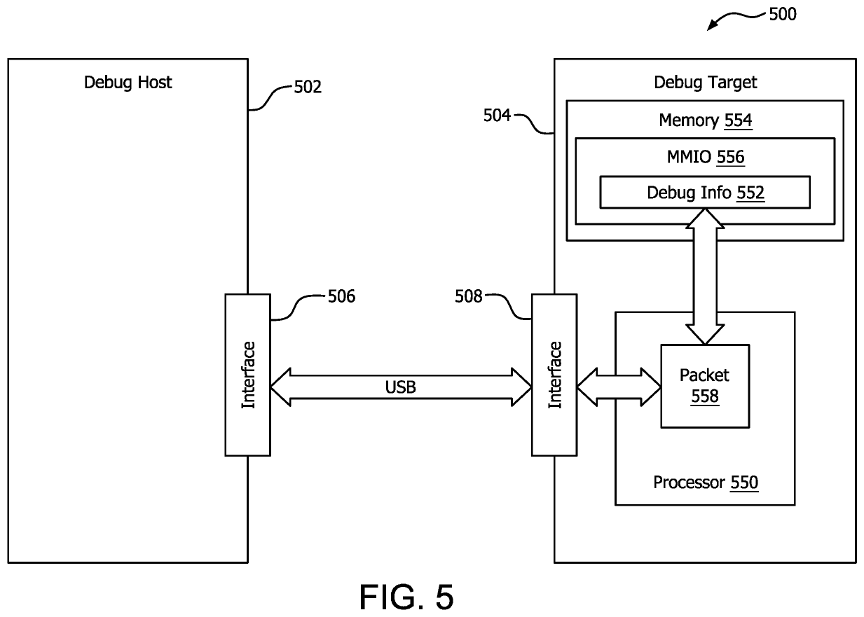

FIG. 5 is a block diagram illustrating an example system 500 configured for silicon debugging. System 500 includes a debugging host 502, and a debugging target 504.

Debugging host 502 includes any suitable computing system or other electronic hardware configured to transmit debugging commands to, and receive debugging data from, a debugging target for debugging (e.g., silicon debugging) purposes, such as analysis of signals. Debugging host 502 includes a communications interface 506. Debugging target 504 includes any suitable debugging target, such as debugging target 200 as shown and described with respect to FIG. 2, or any suitable SoC or other IC or closed chassis system. Debugging target 504 includes a communications interface 508.

In some implementations, communications interface 508 and communications interface 506 are host interfaces (e.g. USB4 host interfaces), and in some implementations, debugging host 502 and debugging target 504 are configured to communicate using host-to-host communications (e.g., USB4 Host-to-Host communications).

During debugging operations, processor 550 of debug target 504 stores debugging information 552 in memory 554 of debug target 504. In some implementations, debugging information 552 is stored in a memory that is addressed by part of the memory-mapped input-output (MMIO) space 556 of memory 554. In some such implementations, additional MMIO space is allocated, beyond addresses needed for I/O functionality, to store debugging information 552. For example, in some implementations, extra MMIO space is declared in the same BAR as a USB4 host interface adapter, or an additional BAR is declared.

Processor 550 (or any other suitable hardware of debug target 504) is configured to read debug information 552 from memory 554 and to encapsulate it in a packet 558, such as a USB4 packet (e.g., a USB4 interdomain packet). Debug target 504 sends packet 558 to debug host 502 over communications interface 508 and communications interface 506 using USB4 host-to-host communications.

In some implementations, transmitting USB4-encapsulated debugging information in this way provides the advantage of facilitating relatively higher speed transmission of debugging information without an intermediary device.

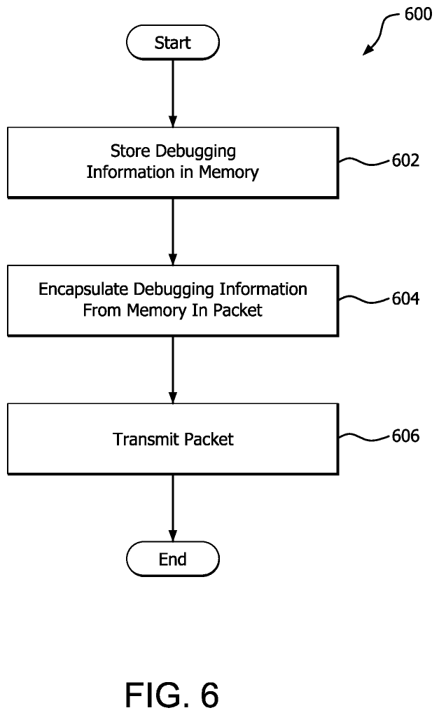

FIG. 6 is a flow chart illustrating an example procedure 600 for transmitting debugging information from a debugging target to a debugging host. Procedure 600 is usable, for example, with system 500 as shown and described with respect to FIG. 5.

In 602, a debugging target stores debugging information in memory. In some implementations, the debugging target stores the debugging information in memory mapped to a MMIO space. In some implementations, the debugging information is stored in additional MMIO space allocated for this purpose. In some implementations, a base address of the portion of the MMIO space allocated for storing the debugging information is indicated in a base address register (BAR) of the debugging target.

In 604, the debugging target (e.g., a processor of the debugging target) retrieves the debugging information from memory, and encapsulates the debugging information in a packet. In some implementations, the packet is a USB4 packet.

In 606, the debugging target transmits the packet to a debugging host. In some implementations, the debugging target transmits the packet to the debugging host over a tunneling interface (e.g., a USB4 host-to-host tunneling interface, e.g., over a USB4 interface (e.g., type C port and cable) using host-to-host tunneling). In some implementations, the debugging target transmits the packet to the debugging host over a USB4 interface.

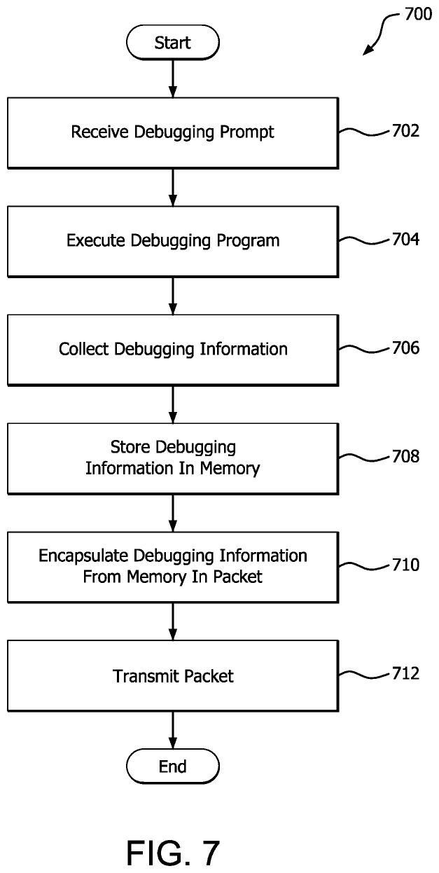

FIG. 7 is a flow chart illustrating an example procedure 700, implemented in a system including a debugging target and a debugging host, for receiving a debugging prompt, executing a debugging program, and transmitting debugging information to a debugging host in a packet, and de-encapsulating the packet. Procedure 700 is usable, for example, with system 500 as shown and described with respect to FIG. 5, and also, for example, with procedure 600 as shown and described with respect to FIG. 6.

In 702, the debugging target receives a debugging prompt (e.g., debugging commands) from a debugging host. In 704, the debugging target executes a debugging program to generate debugging information regarding devices on the debugging target (e.g., based on the debugging commands). In 706, the debugging target collects the debugging information, e.g., from debugging units of the devices on the debugging target.

In 708, the debugging target stores the debugging information in memory. In some implementations, the debugging target stores the debugging information in memory mapped to a MMIO space. In some implementations, the debugging information is stored in additional MMIO space allocated for this purpose. In some implementations, a base address of the portion of the MMIO space allocated for storing the debugging information is indicated in a base address register (BAR) of the debugging target.

In 710, the debugging target retrieves the debugging information from memory, and encapsulates the debugging information in a packet. In some implementations, the packet is a USB4 packet.

In 712, the debugging target transmits the packet to a debugging host. In some implementations, the debugging target transmits the packet to the debugging host over a tunneling interface (e.g., a USB4 host-to-host tunneling interface, e.g., over a USB4 interface (e.g., type C port and cable) using host-to-host tunneling). In some implementations, the debugging target transmits the packet to the debugging host over a USB4 interface.

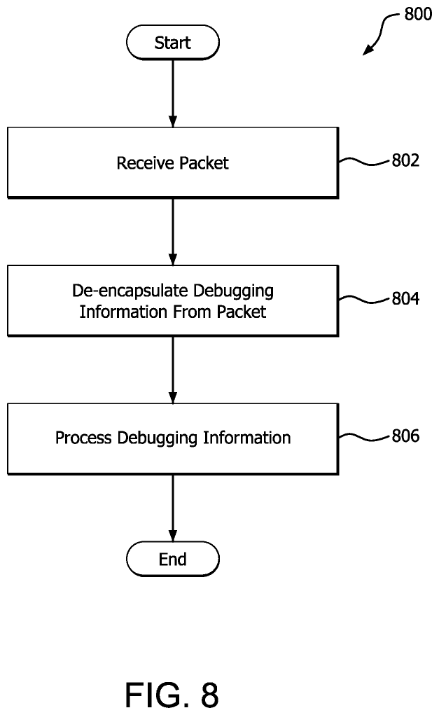

FIG. 8 is a flow chart illustrating an example procedure 800 implemented in a debugging host for receiving a packet from a debugging target, and de-encapsulating the packet to recover and process debugging information. Procedure 800 is usable, for example, with system 500 as shown and described with respect to FIG. 5, and also, for example, with procedure 600 as shown and described with respect to FIG. 6 and/or procedure 700 as shown and described with respect to FIG. 7.

In 802, the debugging host receives a packet from a debugging target. The debugging host includes any suitable computing system or other electronic hardware configured to receive debugging data from a debugging target for silicon debugging purposes, such as analysis of signals. In some implementations, the packet is a USB4 packet. In some implementations, the packet is received over a tunneling protocol from the debugging target (e.g., USB4). In some implementations, the packet is received from the debugging target via a host-to-host communications protocol (e.g., USB4 Host-to-Host communications). In some implementations, a USB4 host of the debugging target sends a packet which includes the debugging data to a USB4 host in the debugging host over a USB4 interface (e.g., type-C port and cable) using Host-to-Host Tunneling.

In 804, the debugging host de-encapsulates the debugging information from the packet, and in 806, the debugging host processes the debugging information (e.g., to provide debugging information to a user).

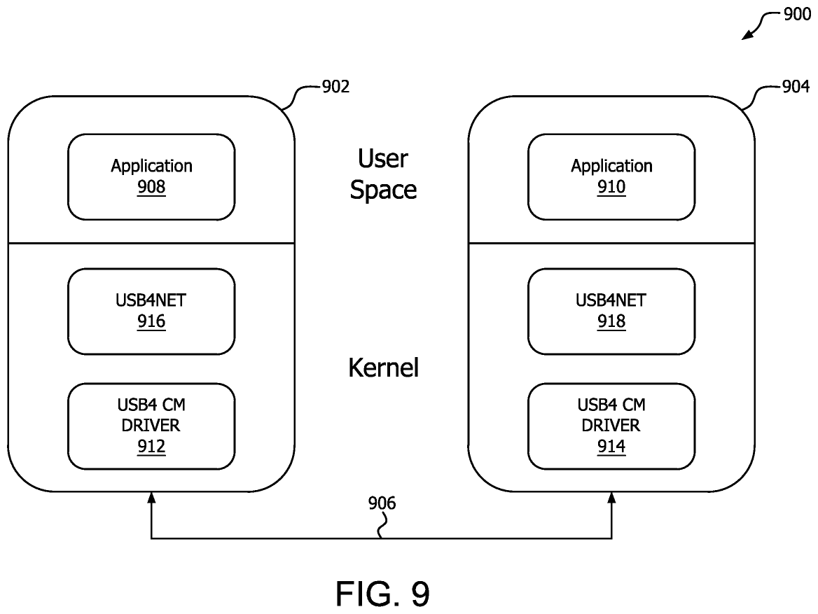

FIG. 9 is a block diagram illustrating an example system 900 for silicon debugging. System 900 includes a debugging host 902, and a debugging target 904.

Debugging host 902 includes any suitable computing system or other electronic hardware configured to receive debugging data from a debugging target for silicon debugging purposes, such as analysis of signals. Debugging target 904 includes any suitable debugging target, such as debugging target 200 as shown and described with respect to FIG. 2, or any suitable SoC or other IC or closed chassis system.

In this example, debugging host 902 and debugging target 904 are in communication over a USB4 communication channel 906. An application 908 running on debugging host 902 sends a socket request over USB4 communication channel 906, to application 910 running on debugging target 904, to request debugging information from a memory on debugging target 904.

The communications over USB4 communication channel 906 are facilitated by USB4 connection manager (USB4CM) drivers 912 and 914, and USB4 interdomain protocol (USB4NET) drivers 916 and 918. USB4CM drivers 912 and 914 facilitate control path functionality for the USB4 communication channel 906. USB4NET drivers 916 and 918 facilitate the host-to-host communication protocol over the USB4 communication channel 906.

In this example, application 910 on debugging target 904 sends a request to USB4CM 914 based on the socket request received from the debugging host 902. USB4CM 914 maps the physical address of the memory (e.g., DRAM) on debugging target 904 and provides the debugging information to application 910.

Application 910 sends the debugging information to application 908 over the USB4 communication channel 906 via a socket send via USB4CM driver 914 (e.g., USB4CM driver 914 encapsulates the debugging information in a USB4 packet (e.g., a USB4 Interdomain packet) and sends it to application 908 over USB4 communication channel 906), and application 908 decodes (e.g., de-encapsulates) and processes the debugging information, e.g., for presentation to a user via a graphical user interface.

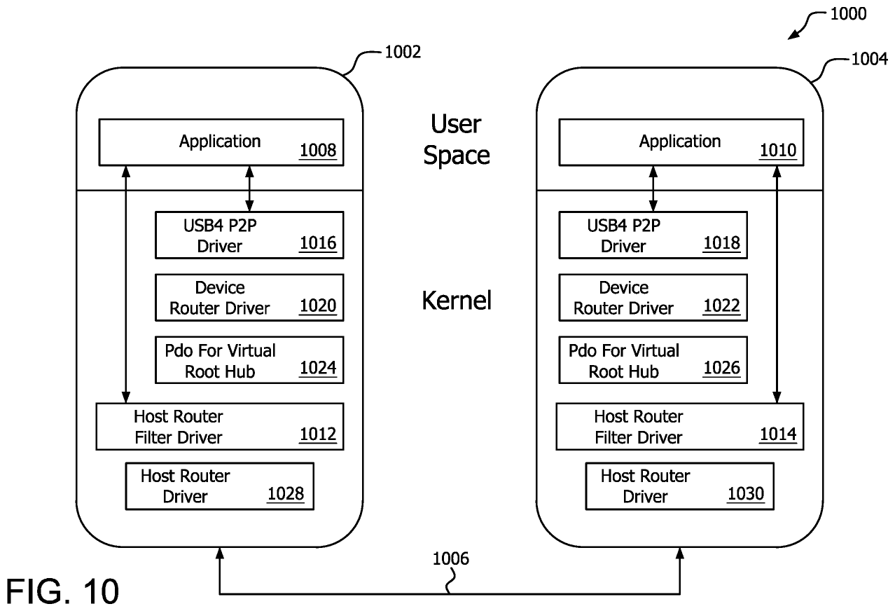

FIG. 10 is a block diagram illustrating an example system 1000 for silicon debugging. System 1000 includes a debugging host 1002, and a debugging target 1004.

Debugging host 1002 includes any suitable computing system or other electronic hardware configured to send debugging commands to a debugging target, and to receive debugging data from the debugging target for silicon debugging purposes, such as analysis of signals. Debugging target 1004 includes any suitable debugging target, such as debugging target 200 as shown and described with respect to FIG. 2, or any suitable SoC or other IC or closed chassis system.

In this example, debugging host 1002 and debugging target 1004 are in communication over a USB4 communication channel 1006. An application 1008 running on debugging host 1002 sends a request over USB4 communication channel 1006, to application 1010 running on debugging target 1004, to request debugging information from a memory on debugging target 1004.

In some implementations, the application 1008 sends a request (e.g., IOCTL) to host router filter driver 1012 to retrieve the debugging information from the memory on debugging target 1004, and host router filter driver 1014 maps the physical address of the memory and provides the address information to application 1010. Application 1010 sends the debugging data returned by host router filter driver 1014 to application 1008 on debugging host 1002 via a packet (e.g., host router filter driver 1014 encapsulates the debugging information in a USB4 packet (e.g., USB4 Interdomain packet) and sends it to application 1008 over USB4 communication channel 1006), and application 1008 decodes (e.g., de-encapsulates) and processes the debugging information, e.g., for presentation to a user via a graphical user interface.

Some implementations include various drivers and objects for implementing USB4 host-to-host communications. In some implementations, operating systems of debugging host 1002 and debugging target 1004 enumerate USB4 drivers responsive to debugging host 1002 and debugging target 1004 being connected using a USB4 interface.

In this example, USB4 peer-to-peer (P2P) drivers 1016, 1018 are virtual network adapters implemented on debugging host 1002 and debugging target 1004, respectively. In some implementations, device routers of debugging host 1002 and debugging target 1004 creates a P2P device object when it detects an interdomain link. This driver is a network driver over the USB4 link.

Device router drivers 1020, 1022 are USB4 device router drivers implemented on debugging host 1002 and debugging target 1004, respectively. In some implementations, device router drivers 1020, 1022 are enumerated for built-in hosts and device routers of debugging host 1002 and debugging target 1004.

Private data objects (PDO) 1024, 1026 are device objects created by a host router to load a virtual root hub.

Host router drivers 1028, 1030 are virtual USB4 host routers implemented on debugging host 1002 and debugging target 1004, respectively. Host router drivers 1028, 1030 abstract components of the host router.

In some implementations, an interdomain link is established between debugging host 1002 and debugging target 1004, and debugging host 1002 and debugging target 1004 will be able to communicate with each other using their respective network stacks. In some implementations, debugging target 1004 reads debugging data from its USB4 MMIO mapped memory (e.g., as discussed herein) and sends the debugging data to debugging host 1002 over the USB4 interface. In some implementations, application 1008 is a socket server, and application 1010 is a corresponding socket client.

It should be understood that many variations are possible based on the disclosure herein. Although features and elements are described above in particular combinations, each feature or element can be used alone without the other features and elements or in various combinations with or without other features and elements.

The various functional units illustrated in the figures and/or described herein (including, but not limited to, the processor 102, the input driver 112, the input devices 108, the output driver 114, the output devices 110, the accelerated processing device 116, the scheduler 136, the graphics processing pipeline 134, the compute units 132, the SIMD units 138, may be implemented as a general purpose computer, a processor, or a processor core, or as a program, software, or firmware, stored in a non-transitory computer readable medium or in another medium, executable by a general purpose computer, a processor, or a processor core. The methods provided can be implemented in a general-purpose computer, a processor, or a processor core. Suitable processors include, by way of example, a general-purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), and/or a state machine. Such processors can be manufactured by configuring a manufacturing process using the results of processed hardware description language (HDL) instructions and other intermediary data including netlists (such instructions capable of being stored on a computer readable media). The results of such processing can be maskworks that are then used in a semiconductor manufacturing process to manufacture a processor which implements features of the disclosure.

The methods or flow charts provided herein can be implemented in a computer program, software, or firmware incorporated in a non-transitory computer-readable storage medium for execution by a general-purpose computer or a processor. Examples of non-transitory computer-readable storage mediums include a read only memory (ROM), a random-access memory (RAM), a register, cache memory, semiconductor memory devices, magnetic media such as internal hard disks and removable disks, magneto-optical media, and optical media such as CD-ROM disks, and digital versatile disks (DVDs).

What is claimed is:

1. A device configured for communicating debugging information, comprising:
a memory configured to store debugging information from debugging circuitry of the device;
a processor configured to retrieve the debugging information from the memory and encapsulate the debugging information in a packet; and
the processor configured to transmit the packet to another device that is external to the device.

2. The device of claim 1, wherein the debugging information is stored in memory mapped input output (MMIO) space of the memory.

3. The device of claim 1, wherein the debugging information is stored in memory mapped input output (MMIO) space of the memory that is not mapped to registers of the device.

4. The device of claim 1, wherein the debugging information is stored in a memory mapped input output (MMIO) space of the memory, wherein a base address of the MMIO is indicated in a base address register (BAR) of the device.

5. The device of claim 1, further comprising circuitry configured to encapsulate the debugging information in a Universal Serial Bus 4 (USB4) packet and to transmit the packet over a USB4 interface to the device that is external to the device.

6. The device of claim 1, further comprising circuitry configured to retrieve the debugging information is retrieved from the memory, encapsulate the debugging information in a packet, and pass the packet to a Universal Serial Bus 4 (USB4) driver for transmission to the device that is external to the device.

7. The device of claim 1, wherein the device transmits the packet to the device that is external to the device via a Universal Serial Bus C (USB-C) interface, Universal Serial Bus 4 (USB4) fabric, and/or USB4 Host-to-Host Tunneling.

8. The device of claim 1, wherein the packet comprises a USB4 interdomain packet or an internet protocol (IP) packet.

9. The device of claim 1, wherein the memory of the device comprises dynamic random-access memory (DRAM).

10. The device of claim 1, wherein encapsulating the debugging information in a packet comprises encapsulating the debugging information in a Universal Serial Bus 4 (USB4) Interdomain Packet.

11. A method for communicating debugging information, the method comprising:
storing debugging information from debugging circuitry of an integrated circuit into a memory;
retrieving the debugging information from the memory and encapsulating the debugging information in a packet; and
transmitting the packet to a device that is external to the integrated circuit.

12. The method of claim 11, wherein the debugging information is stored in memory mapped input output (MMIO) space of the memory.

13. The method of claim 11, wherein the debugging information is stored in memory mapped input output (MMIO) space of the memory that is not mapped to registers of the integrated circuit.

14. The method of claim 11, wherein the debugging information is stored in a memory mapped input output (MMIO) space of the memory, wherein a base address of the MMIO is indicated in a base address register (BAR) of the integrated circuit.

15. The method of claim 11, wherein the debugging information is encapsulated in a Universal Serial Bus 4 (USB4) packet and transmitted over a USB4 interface to the device that is external to the integrated circuit.

16. The method of claim 11, wherein the debugging information is retrieved from the memory, encapsulated in a packet, and passed to a Universal Serial Bus 4 (USB4) driver for transmission to the device that is external to the integrated circuit.

17. The method of claim 11, wherein the integrated circuit transmits the encapsulated debugging information to the device that is external to the integrated circuit via a Universal Serial Bus C (USB-C) interface, Universal Serial Bus 4 (USB4) fabric, and/or USB4 Host-to-Host Tunneling.

18. The method of claim 11, wherein the packet comprises a USB4 interdomain packet or an internet protocol (IP) packet.

19. The method of claim 11, wherein the memory of the integrated circuit comprises dynamic random-access memory (DRAM).

20. The method of claim 11, wherein encapsulating the debugging information in a packet comprises encapsulating the debugging information in a Universal Serial Bus 4 (USB4) Interdomain Packet.
